(19) United States
(12) Patent Application Publication
(10) Pub. No.: US 2010/0048018 A1
(43) Pub. Date: Feb. 25, 2010

(54) Doped Layers for Reducing Electromigration

(75) Inventors: Atul Gupta, Beverly, MA (US); Heyun Yin, Saugus, MA (US); Vikram Singh, North Andover, MA (US)

Correspondence Address: RAUSCHENBACH PATENT LAW GROUP, LLC, P.O. BOX 387, BEDFORD, MA, 01730, US

(73) Assignee: Varian Semiconductor Equipment Associates, Inc., Gloucester, MA (US)

(21) Appl. No.: 12/198,083

(22) Filed: Aug. 25, 2008

(51) Int. Cl. H01L 21/768

(52) U.S. Cl. 438/658; 257/E21.591

(57) ABSTRACT

A method of fabricating metal interconnects with reduced electromigration includes depositing metal interconnects on a substrate comprising electronic devices. A layer is deposited on the metal interconnects. The layer is doped with at least one dopant having a dopant concentration that increases an electromigration resistance of the metal atoms.

The section headings used herein are for organizational purposes only and should not to be construed as limiting the subject matter described in the present application.

### BACKGROUND OF THE INVENTION

Circuit designers and integrated circuit manufactures have steadily reduced the line widths of metal interconnects over the last half century following what is known as Moore's Law, which is an observation made by Intel's co-founder Gordon E. Moore in 1965. Moore's Law states that the number of transistors which can be inexpensively placed on an integrated circuit is increasing exponentially, doubling approximately every two years. The trend described by Moore's Law has been remarkably accurate and is not expected to end for another decade and perhaps for a much longer time period.

The continuing reduction in the line widths of the metal interconnects has resulted in a continuing increase in current density that is carried through these smaller and smaller metal interconnects. The higher current densities being supported in metal interconnects cause a higher transfer of momentum from the electrons to the metal atoms. This increase in the transferred momentum to the metal atoms has led to an increase in electromigration in these metal interconnects. Electromigration is the movement of metal atoms under the influence of an electric field. It is generally accepted that protection against electromigration needs to improve at least twofold for every device generation.

### BRIEF DESCRIPTION OF THE DRAWINGS

The aspects of this invention may be better understood by referring to the following description in conjunction with the accompanying drawings. Identical or similar elements in these figures may be designated by the same reference numerals. Detailed description about these similar elements may not be repeated. The drawings are not necessarily to scale. The skilled artisan will understand that the drawings, described below, are for illustration purposes only. The drawings are not intended to limit the scope of the present teachings in any way.

FIG. 1 presents a diagram of a copper interconnect in an integrated circuit that shows various paths available for metal atoms to diffuse under the influence of an electric current.

FIG. 2 presents a cross-sectional diagram of a copper interconnect in an integrated circuit that illustrates the copper/dielectric etch stop layer interface where the most significant electromigration occurs.

FIG. 3 illustrates one embodiment of a process for fabricating copper interconnects with reduced electromigration according to the present invention that exposes the copper interconnects to a gas containing Group 4A, 5A, 6A element dopant atoms before depositing the etch stop dielectric layer.

FIG. 4 illustrates one embodiment of a process for fabricating copper interconnects with reduced electromigration according to the present invention that includes depositing a film including Group 5A and Group 6A element dopant atoms before depositing the etch stop dielectric layer.

FIG. 5 illustrates one embodiment of a process for fabricating copper interconnects with reduced electromigration according to the present invention that includes depositing an etch stop dielectric layer that includes Group 5A and Group 6A element dopant atoms.

FIG. 6 illustrates one embodiment of a process for fabricating copper interconnects with reduced electromigration according to the present invention that uses ion implantation to implant Group 5A and Group 6A element dopant ions into the dielectric etch stop layer.

FIG. 7 presents plots of fraction of device failures due to interconnect failures as a function of time to failure for devices fabricated according to known methods and for devices fabricated according to the methods of the present invention.

### DETAILED DESCRIPTION

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

It should be understood that the individual steps of the methods of the present invention may be performed in any order and/or simultaneously as long as the invention remains operable. Furthermore, it should be understood that the apparatus and methods of the present invention can include any number or all of the described embodiments as long as the invention remains operable.

The present teachings will now be described in more detail with reference to exemplary embodiments thereof as shown in the accompanying drawings. While the present teachings are described in conjunction with various embodiments and examples, it is not intended that the present teachings be limited to such embodiments. On the contrary, the present teachings encompass various alternatives, modifications and equivalents, as will be appreciated by those of skill in the art. Those of ordinary skill in the art having access to the teachings herein will recognize additional implementations, modifications, and embodiments, as well as other fields of use, which are within the scope of the present disclosure as described herein.

For example, although some embodiments of the present invention are described in connection with copper interconnects, one skilled in the art will appreciate that the methods of reducing electromigration according to the present invention are not limited to use with copper interconnects. In particular, the methods for reducing electromigration of the present invention can be practiced with any type of interconnect, such as Al, Ag, Au, Ti, Ta, and W interconnects.

Also, it should be understood that the methods for reducing electromigration according to the present invention can be practiced with any one of numerous types of deposition and/or doping techniques. For example, the methods for reducing electromigration according to the present invention can be practiced with chemical vapor deposition, catalytic chemical vapor deposition, reduced pressure chemical vapor deposition, plasma enhanced chemical vapor deposition, physical vapor deposition, atomic layer deposition, electrochemical deposition, ion beam assisted deposition, diffusion, conventional beam line ion implantation, and plasma doping.

In addition, it should be understood that the methods for reducing electromigration according to the present invention can be practiced by depositing numerous type of layers. In particular, the methods for reducing electromigration according to the present invention are not limited to using dielectric barrier layers. For example, the layers can include dielectric, semiconductor, and metallic layers.

Electromigration in metal interconnects is caused when electrical signals with relatively high current densities propagate through these interconnects causing metal atoms to drift or diffuse with the electron gas generated by the high current densities. The direction of the electron gas flow is opposite to the direction of current flow. Metal atoms can diffuse along grain boundaries, along the track surface, or through the metal grains. There are preferential directions for this diffusion. For example, diffusion in aluminum interconnects occurs preferentially along grain boundaries. Diffusion in copper lines occurs preferentially along the surface of copper interconnects where they interface with dielectric material in the integrate circuit.

The diffusing of the metal atoms caused by electromigration results in voids and hillock formation in interconnects. These voids and hillock formations result in a locally high resistance that causes local heating which can result in decreases of both device yield and lifetime. The voids and hillock formations can also result in an open circuit in an interconnect, which can cause a device failure. In addition, the geometric constraints of the surrounding dielectric on narrow line width interconnects reduce the ability of the interconnects to relax induced stress by plastic deformation. The inability to relax induced stress results in stress-migration can also lead to locally high resistance and open circuits that can cause device failures.

The decrease in both device yield and lifetime due to electromigration is currently being experienced in state-of-the-art complementary metal-oxide-semiconductor (CMOS) integrated circuits. These CMOS integrated circuits are widely used today because they combine relatively low power consumption with relatively high performance. State-of-the-art CMOS devices use thin closely spaced interconnects to conduct electrical current to and from the transistors and other electronic components in the integrated circuit device. Electromigration in metal interconnections is currently a major factor that limits yield in back-end processing of CMOS devices.

Recently, the performance of metal interconnects in CMOS and other devices has been improved by using copper-based metallization instead of the conventional aluminum-based metalization. Copper based metallization has lower electromigration than aluminum based metallization because copper has a lower atomic diffusivity than aluminum. In addition, copper is a desirable material for interconnects because it has relatively low resistivity, which is significantly lower than aluminum. The relatively low resistivity of copper in copper interconnects results in a lower associated RC time delay. Currently, RC time delays associated with interconnects are an increasing limitation in narrow line width interconnects because they have relatively high capacitance due to their small geometries. For example, the SIA/SEMATECH roadmap indicated that for 0.25 μm device features, copper interconnects reduce the RC delay times by about 35% and increase device lifetimes by two to four orders of magnitude compared with devices having aluminum interconnects.

Copper interconnects are more difficult to fabricate than aluminum interconnects because they must be isolated from both Si and SiO2 layers by a barrier layer to prevent metal migration. For example, alternating layers of tantalum nitride and tantalum can be used. In addition, copper interconnects lack the oxidation and corrosion resistance of conventional aluminum interconnects and, therefore, require better packaging. Copper interconnects can also suffer from poor substrate adhesion.

Electromigration is, however, the most serious reliability problem in copper interconnects and is the major cause of failure in copper interconnects. The most significant electromigration occurs at the top surface of the copper, where it interfaces with the overlying dielectric, which is typically a silicon carbide (SiC) or a silicon carbon nitride (SiCN) barrier layer. Electromigration can also occur at the interface between the copper and the barrier material.

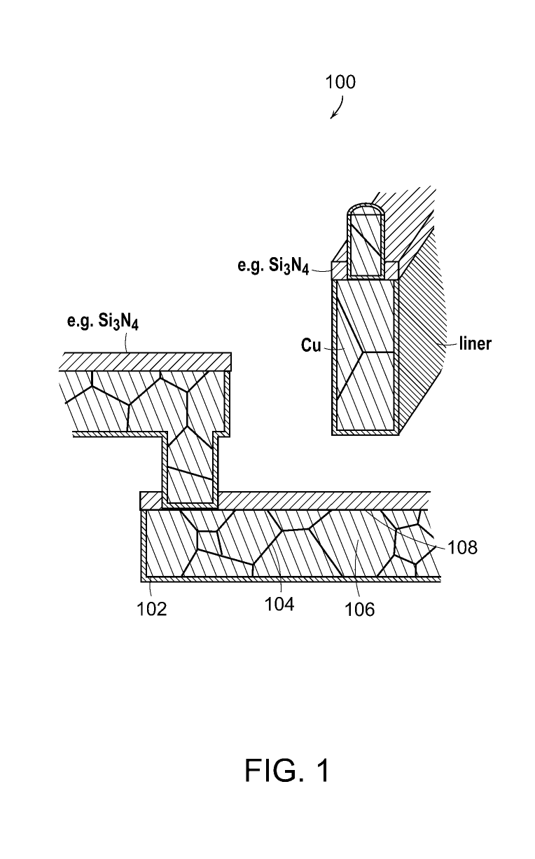

FIG. 1 presents a diagram of a copper interconnect 100 in an integrated circuit that shows various paths available for metal atoms to diffuse under the influence of an electric current. Diffusion of copper atoms under the influence of an electric current occurs along the barrier metal interface 102 with a diffusion coefficient D_{int(Barrier)}. Diffusion of copper atoms under the influence of an electric current also occurs along the grain boundaries 104 with a diffusion coefficient D_{gb}. In addition, diffusion of copper atoms under the influence of an electric current occurs in the copper layer 106 with a diffusion coefficient D_{L}. Furthermore, diffusion of copper atoms under the influence of an electric current also occurs along the silicon nitride interface layer 108 with a diffusion coefficient D_{int(SiN)}.

In general, the value of the diffusion coefficient D_{int(SiN)} along the silicon nitride interface layer 108 is greatest. The value of the diffusion coefficient D_{int(Barrier)} along the metal barrier interface 102 is generally lower than the value of the diffusion coefficient D_{int(SiN)} along the silicon nitride interface layer 108. The value of the diffusion coefficient D_{gb} along the grain boundaries 104 is generally lower than the value of the value of the diffusion coefficient D_{int(Barrier)} along the barrier metal interface 102. In addition, the value of the diffusion coefficient D_{L} in the copper layer is generally lower than the value of the diffusion coefficient D_{gb} along the grain boundaries 104.

The degree of electromigration is proportional to the diffusion coefficient. The diffusion along various paths significantly varies with diffusion being highest along the silicon nitride interface layer 108 and being lowest in the copper layer 106. Copper interconnects fabricated with the Damascene process have the highest copper diffusion rate at the copper silicon nitride interface layer 108.

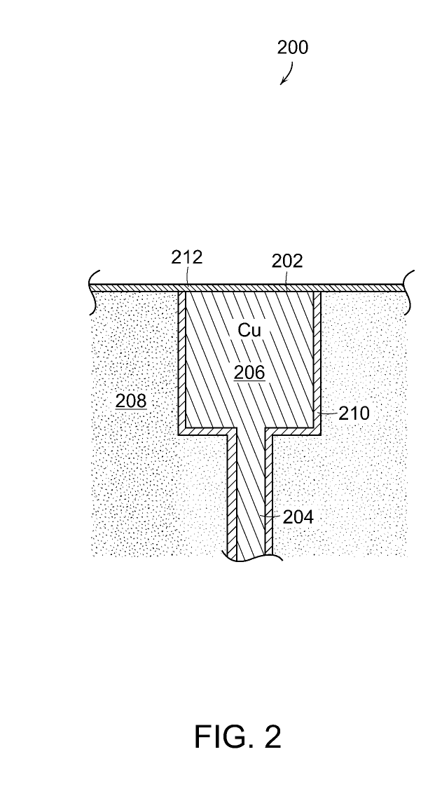

FIG. 2 presents a cross-sectional diagram of a copper interconnect 200 in an integrated circuit that illustrates the copper/dielectric etch stop layer interface 202 where the most significant electromigration occurs. The cross-sectional diagram 200 shows the copper filed via 204. The copper filed via 204 connects one layer of the integrated circuit to another layer of the integrated circuit. In addition, the cross-sectional diagram 200 shows the copper filed trench 206 across the substrate.

The copper filed via 204 and the copper filed trench 206 both are formed into interlayer dielectric material 208, which is a low dielectric constant material. The interlayer dielectric material 208 is commonly used to reduce the RC time delay, which improves device performance. A barrier metal layer 210 surrounds the copper interconnect 200 and prevents copper migration from the copper interconnect 200 into the interlayer dielectric material 208. For example, the barrier metal layers can be alternating layers of TaN and Ta.

A dielectric etch stop layer 212 is deposited on the top surface of the copper interconnect 200. In one embodiment, the dielectric etch stop layer is SiNₓ that is deposited by plasma enhanced chemical vapor deposition, which is a well known deposition technique in the industry. In another embodiment, the dielectric etch stop layer is a SiC_{y} or a SiCN/SiCO layer that is deposited by plasma enhanced chemical vapor deposition. The SiC_{y} dielectric layer has a lower dielectric constant compared with SiNₓ and, therefore, has a lower associated RC time delay, which can improve device performance. However, SiC_{y} dielectric layers are more difficult to deposit.

The copper/dielectric etch stop layer interface 202 is typically where the most significant electromigration occurs because it typically has the highest metal diffusion coefficient. There have been several attempts to reduce electromigration from the copper interconnect to a silicon nitride etch stop layer. In one known method, copper interconnects are alloyed with other metals to reduce electromigration. However, metal impurities resulting from the alloying process have resulted in an increase in leakage between interconnects, which has resulted in poor device performance.

In other known methods, ion implantation is used to add impurities into the copper composition in order to improve the resistance of the copper dielectric material interface to electromigration. The copper composition is deposited and then impurities, such as C, O, Cl, S, and N are implanted at suitable concentrations that range from about 0.01 ppm by weight to about 1,000 ppm by weight. One known method deposits a copper seed layer into a receptacle, ion implants the seed layer, and then electroplates the remainder of the copper interconnect into the receptacle. Another known method deposits a copper seed layer into a receptacle and then electrodeposits a copper composition containing impurities into the receptacle. The resulting structures are then annealed so that impurities diffuse into the copper seed layer. In another known method, a barrier layer is first deposited into a receptacle. Ions are then implanted into the barrier layer. A copper seed layer is then deposited on top of the barrier layer. The structure is then annealed so that dopant ions diffuse into the copper seed layer. In other known methods, dopants are implanted into the surface layer of the copper interconnect to provide resistance to electromigration.

Some known methods of using ion implantation to add impurities into the copper composition in order to improve the electromigration resistance result in the introduction of additional damage to the interlayer dielectric material between interconnects, which increases the effective dielectric constant (k_{eff}) of the interlayer dielectric. Consequently, these ion implantation methods tend to result in reduced device performance.

One aspect of the present invention is the use of doped layers to reduce electromigration without significantly reducing the performance of the device. Such doped layers increase the yield and the lifetime of the device and will enable the anticipated continued reduction in interconnect line widths. In various embodiments, the layer can be a dielectric barrier layer, a semiconductor layer, or a metal layer. A dielectric barrier layer is described in more detail herein. However, is should be understood that numerous types of layers can be used that that these layers are not limited to dielectric, semiconductor and metal layers.

In one embodiment, a dielectric barrier layer is doped at the copper/dielectric etch stop layer interface 202 shown in FIG. 2. In another embodiment, the dielectric layer is continuously doped through the entire dielectric layer. In various other embodiments, the dielectric barrier layer is doped in any region of the layer. For example, the dielectric barrier layer can be doped with a graded dopant profile.

A graded dopant profile can be achieved during doping or can be achieved by a post processing means, such as by annealing in an inert or a reactive ambient. The dopant migrates into the dielectric barrier layer during annealing. Also, a chemical reaction between the metal surface and the dielectric barrier layer can be triggered during post annealing. Also, graded dopant profiles can be achieved by performing various photochemical or electrochemical reactions. In addition, graded dopant profiles can be achieved by performing various electrochemical reactions.

In one embodiment, the metal/dielectric etch stop interface 202 is doped with at least one Group 5A and Group 6A element in the periodic table except for nitrogen. It has been determined that doping dielectric layers with Group 5A and Group 6A elements, such as P, As, Se, and Te, greatly reduces metal migration along the metal/dielectric layer interface. Doping dielectric layers with these elements will reduce electromigration from the metal interconnect to the dielectric layer and will reduce charge leakage between interconnects. In addition, it has been determined that Group 5A and Group 6A periodic table element dopants, such as P, As, Se, and Te, do not significantly increase the dielectric constant of the interlayer dielectric material.

Group 5A and Group 6A element dopants, such as P, As, Se, and Te are particularly suitable for forming an interface that has relatively high resistance to electromigration or that prevents electromigration because these elements can form more than two bonds with various atoms. Therefore, these elements are likely to improve the interface strength through bonding between the top surface of the copper and the bottom surface of the etch stop or other dielectric layer.

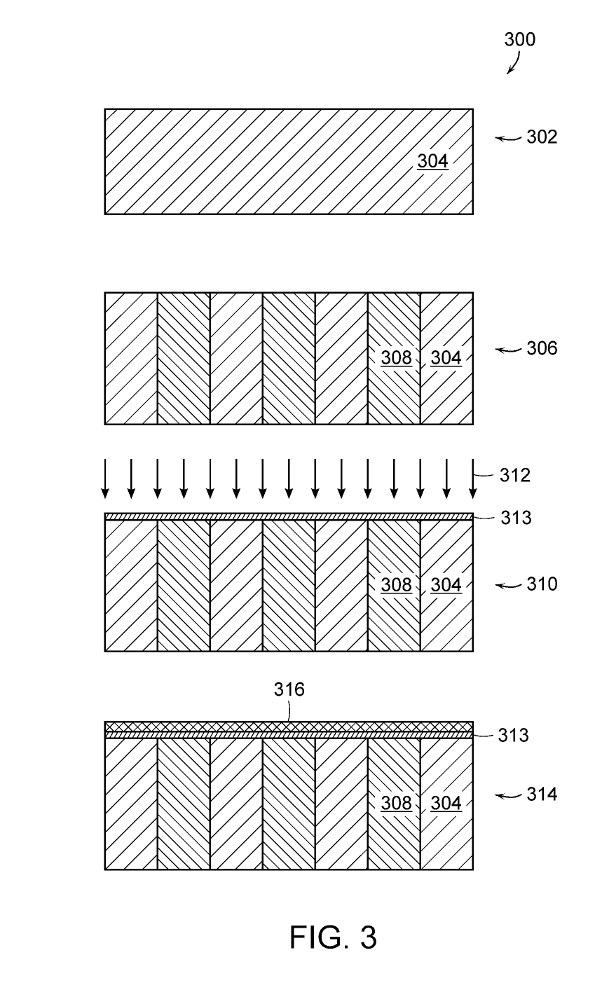

FIG. 3 illustrates one embodiment of a process 300 for fabricating copper interconnects with reduced electromigration according to the present invention that exposes the copper interconnects to a gas containing Group 4A, 5A, or Group 6A element dopant atoms before depositing the etch stop dielectric layer. For illustration purposes, one layer of metallization is shown. It should be understood that in most devices there are many different layers of metallization.

In a first step 302, the substrate 304 is cleaned prior to metal and dielectric deposition. For example, the substrate 304 can be cleaned by performing a Chemical Mechanical Planarization (CMP) step that is used to remove material from uneven topography on a wafer surface until a flat (planarized) surface is created. The CMP step combines the chemical removal effect of an acidic or basic fluid solution with the “mechanical” effect provided by polishing the surface with an abrasive material. Performing the CMP step allows subsequent photolithography to take place with greater accuracy, and enables film layers to be built up with minimal height variations.

In a second step 306, copper interconnects 308 are fabricated in the substrate 304. There are numerous methods of fabricating copper interconnects on substrates that are well known in the art. Any method of fabricating copper interconnects can be used. In a third step (not shown), the substrate 304 and the copper interconnects 308 are cleaned in preparation for depositing the dielectric etch stop layer. For example, the substrate 304 and the copper interconnects 308 can be cleaned by various means including a NH₃ plasma process, a N₂/H₂ plasma process, and/or substrate heat treatments with process parameters that are chosen to remove or reduce the native copper oxides that form on the exposed copper surfaces of the interconnects 308.

In a fourth step 310, the cleaned substrate 304 and the copper interconnects 308 are exposed to gas atoms 312 containing the Group 4A, 5A, or Group 6A element dopants, such as P, As, and Se, that are suitable for forming an interface with relatively high resistance to electromigration. For example, the cleaned substrate 304 and the copper interconnects 308 can be exposed to PH₃ or AsH₃ gas at temperatures that are between 20 degrees C. and 500 degrees C. before depositing the dielectric etch stop layer. Using PH₃ gas will deposit Phosphorus (P) atoms on the surface of the copper interconnects. Using AsH₃ gas will deposit Arsenic (As) atoms in a thin layer 313 on the surface of the copper interconnects. In many embodiments, only a few monolayers of atoms are required to provide sufficient resistance to electromigration. It should be understood that the thin layer 313 is not shown to scale.

In a fifth step 314, a dielectric etch stop layer 316 is deposited on the substrate 304 and copper interconnects with the Group 4A, 5A, or Group 6A element dopant atoms, such as P, As, Se, and Te atoms, that are suitable for forming an interface with relatively high resistance to electromigration. Any dielectric etch stop layer can be used with the methods of the present invention. For example, a SiNₓ dielectric etch stop layer can be deposited in a reactor at temperatures that are between about 100 degrees C. and 450 degrees C. Alternatively, a SiC_{y} dielectric layer can be deposited.

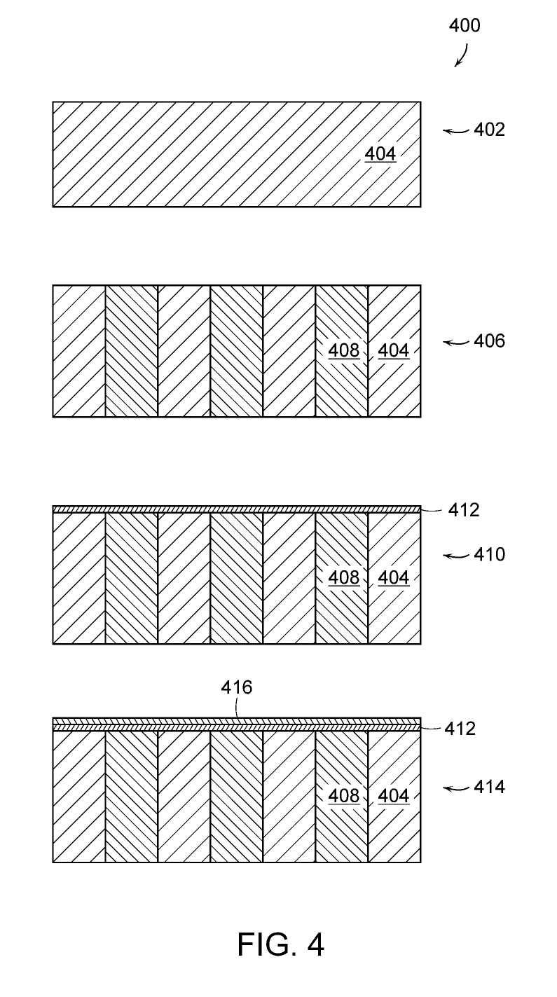

FIG. 4 illustrates one embodiment of a process 400 for fabricating copper interconnects with reduced electromigration according to the present invention that includes depositing a film including Group 5A or Group 6A element dopant atoms before depositing the etch stop dielectric layer. For illustration purposes, one layer of metallization is shown. It should be understood that in most devices there are many different layers of metallization. The process 400 is similar to the process 300 that was described in connection with FIG. 3.

In a first step 402, the substrate 404 is cleaned prior to metal and dielectric deposition. For example, the substrate 404 can be cleaned by performing a CMP step. In a second step 406, copper interconnects 408 are fabricated in the substrate 404. Any method of fabricating copper interconnects can be used. In a third step (not shown), the substrate 404 and the copper interconnects 408 are cleaned in preparation for depositing the dielectric etch stop layer. For example, the substrate 404 and the copper interconnects 408 can be cleaned with a NH₃ plasma process.

In a fourth step 410, a Group 5A or Group 6A element dopant containing layer 412 of dielectric material is deposited on the cleaned substrate 404 and the copper interconnects 408 with film parameters that are suitable for forming an interface with relatively high resistance to electromigration. For example, a P, As, Se, and Te dopant containing layer of dielectric material can be deposited at temperatures ranging from about 100 degrees C. to 500 degrees C. by chemical vapor deposition. In one embodiment, the Group 5A or Group 6A element dopant containing layer 412 is deposited with a thickness that is between 1-30 nm thick. In other embodiments, the Group 5A or Group 6A element dopant containing layer 412 is deposited with a thickness greater than 30 nm.

In a fifth step 414, the dielectric etch stop layer 416 is deposited on the substrate 404 and copper interconnects 408 with the Group 5A or Group 6A element dopant rich layer 412. Any dielectric etch stop layer can be used with the method of the present invention. For example, a SiNₓ dielectric etch stop layer can be deposited in a reactor that typically has temperatures that are between about 100 degrees C. and 450 degrees C. Alternatively, a SiC_{y} dielectric layer can be deposited.

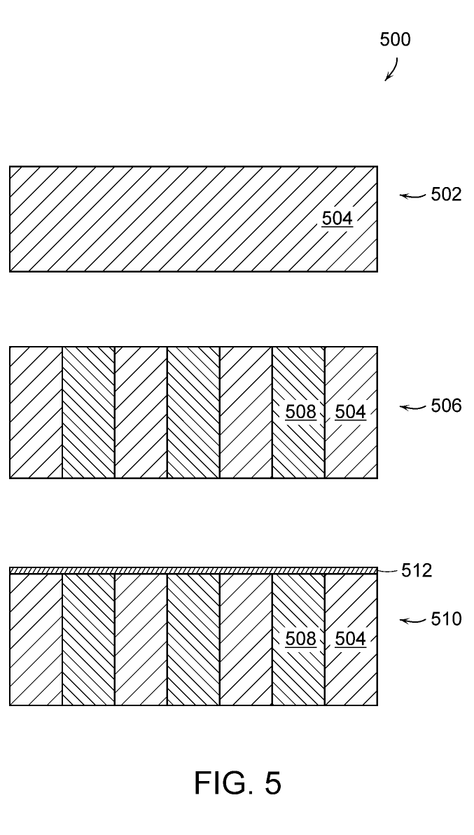

FIG. 5 illustrates one embodiment of a process 500 for fabricating copper interconnects with reduced electromigration according to the present invention that includes depositing an etch stop dielectric layer that includes Group 5A or Group 6A element dopant atoms. For illustration purposes, one layer of metallization is shown. It should be understood that in most devices there are many different layers of metallization.

In a first step 502, the substrate 504 is cleaned prior to metal and dielectric deposition. For example, the substrate 504 can be cleaned by performing a CMP step. In a second step 506, copper interconnects 508 are fabricated in the substrate 504. Any method of fabricating copper interconnects can be used. In a third step (not shown), the substrate 504 and the copper interconnects 508 are cleaned in preparation for depositing the dielectric etch stop layer. For example, the substrate 504 and the copper interconnects 508 can be cleaned with a NH₃ plasma process.

In a fourth step 510, a dielectric etch stop layer 512 is deposited on the cleaned substrate 504 and the copper interconnects 508 with Group 5A or Group 6A element dopant atoms intrinsic to the dielectric etch stop layer material. There are many possible methods of depositing the dielectric etch stop layer 512 with the Group 5A or Group 6A element dopant material intrinsic to the film. In one embodiment, the Group 5A or Group 6A element dopant material is deposited so that the dopant material has substantially the same constituents elements throughout the thickness of the film.

In other embodiments, the Group 5A or Group 6A element dopant material is deposited so that the dopant material has a predetermined composition gradient that achieves a desired resistance to electromigration. A predetermined composition gradient can be obtained by dynamically changing the process conditions of the dielectric etch stop layer 512 during the deposition. For example, the Group 5A or Group 6A element dopant material can be deposited so that the dopant material has a desired concentration proximate to the surface of the copper interconnects 508.

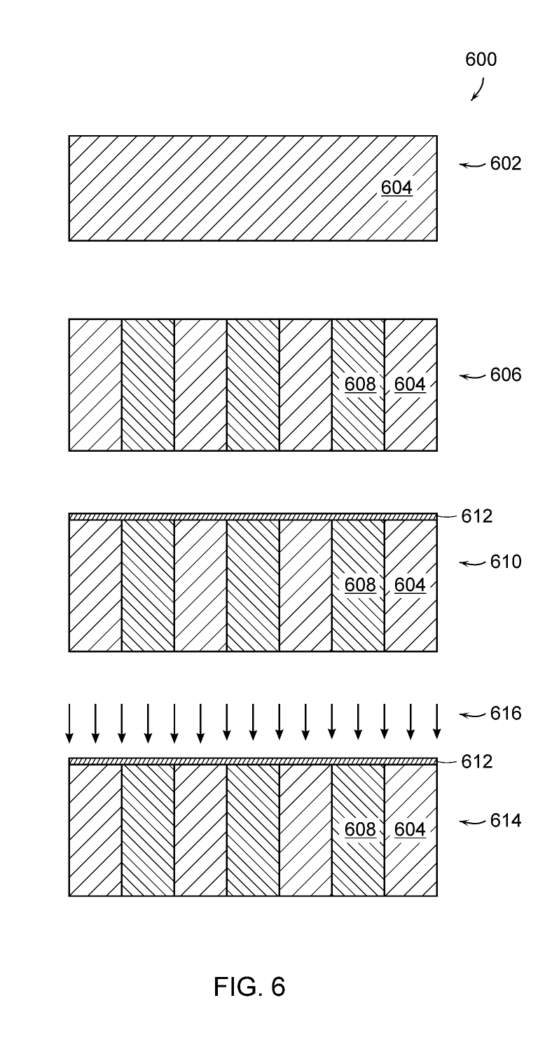

FIG. 6 illustrates one embodiment of a process 600 for fabricating copper interconnects with reduced electromigration according to the present invention that uses ion implantation to implant Group 5A or Group 6A element dopant ions into the dielectric etch stop layer. The process 600 is similar to the process 500 that was described in connection with FIG. 5. In a first step 602, the substrate 604 is cleaned prior to metal and dielectric deposition. For example, the substrate 604 can be cleaned by performing a CMP step. In a second step 606, copper interconnects 608 are fabricated in the substrate 604. Any method of fabricating copper interconnects can be used. In a third step (not shown), the substrate 604 and the copper interconnects 608 are cleaned in preparation for depositing the dielectric etch stop layer. For example, the substrate 604 and the copper interconnects 608 can be cleaned with a NH₃ plasma process. In a fourth step 610, a dielectric etch stop layer 612 is deposited on the cleaned substrate 604 and the copper interconnects 608.

In a fifth step 614, Group 5A or Group 6A element dopant ions 616 are implanted into the dielectric etch stop layer 612. Any type of ion implantation, such as beam line ion implantation, cluster beam ion implantation, and plasma doping can be used. The projected range and dose of the ion implant are chosen to ion implant dopant ions so as to achieve a desired resistance to electromigration.

Any type of ion implantation can be used to implant the Group 5A or Group 6A element dopant ions into the dielectric etch stop layer 612. Ion implantation has been used in the semiconductor and other industries for many decades to modify the composition of substrate material. In particular, beam-line and cluster beam ion implantation systems are widely used today in the semiconductor industry. Beam-line and cluster beam ion implantation systems accelerate ions with an electric field and then select ions with the desired mass-to-charge ratio. The selected ions are then implanted into the dielectric etch stop layer 612, thereby doping the dielectric etch stop layer with the desired dopant material. These systems have excellent process control, excellent run-to-run uniformity, and provide highly uniform doping across the entire surface of state-of-the art semiconductor substrates. Beam-line and cluster beam ion implantation systems can implant the Group 5A or Group 6A element dopant atoms to relatively large projected ranges. In one embodiment, beam line ion implanting is used to implant Group 5A or Group 6A element dopant atoms at or proximate to the interface between the copper interconnect 608 and the dielectric etch stop layer 612 to achieve a desired resistance to electromigration.

Recently, plasma doping has been used to dope substrates. Plasma doping is sometimes referred to as PLAD or plasma immersion ion implantation (PIII). Plasma doping systems have been developed to meet the doping requirements of state-of-the-art electronic and optical devices. Plasma doping systems immerse the substrate in a plasma containing dopant ions and then bias the substrate with a series of negative voltage pulses. The negative bias on the substrate repels electrons from the surface of the substrate, thereby creating a sheath of positive ions. The electric field within the plasma sheath accelerates ions toward the substrate, thereby implanting the ions into the surface of the substrate.

Plasma doping is particularly useful for applications that require very precise control of the depth of dopant profiles. The control of the dopant profile in the substrate depends on the relative abundance of each ion species as well as the particular ion energy distribution prior to entering the surface of the substrate. Plasma doping ion implant profiles are essentially a combination of many individual ion implantation profiles where each of the individual ion profiles has a particular ion energy distribution. The combined ion implant profile reflects the relative number of ions in each of the individual ion profiles that enter into the surface of the substrate. In one embodiment, plasma doping is used to implant Group 5A or Group 6A element dopant atoms at or proximate to the interface between the copper interconnect 608 and the dielectric etch stop layer 612 to achieve a desired resistance to electromigration.

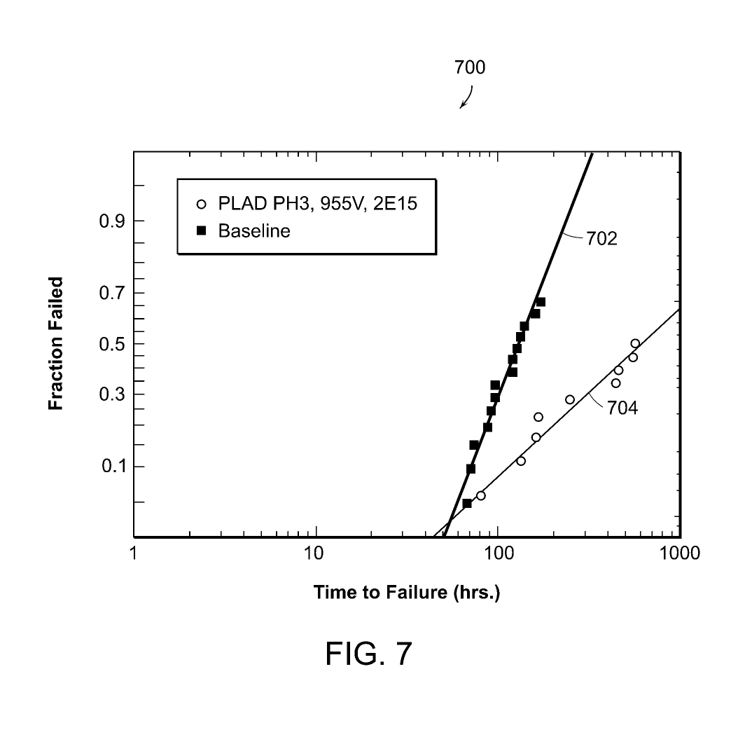

FIG. 7 presents plots 700 of fraction of device failures due to interconnect failures as a function of time to failure for devices fabricated according to known methods and for devices fabricated according to the methods of the present invention. The plot 702 is a plot of fraction of device failures due to interconnect failures as a function of time in hours for devices fabricated according to known methods where copper electromigration is known to occur.

The plot 704 is a plot of fraction of device failures due to interconnect failures as a function of time in hours for devices having dielectric etch stop layers doped with phosphorus according to the present invention. The data in plot 704 was taken for devices fabricated by plasma doping the dielectric etch stop layer with PH₃ at a 955 Volt bias voltage. The dose was 2 10¹⁵. Comparing the data in plot 702 with the data in plot 704 clearly shows the effects of the phosphorus plasma ion implantation on copper electromigration. The failure rate of devices fabricated with phosphorus plasma doping at 600 hours was a 50% failure rate. In contrast, the failure rate of devices fabricated according to known methods was a nearly 100% failure rate.

### Equivalents

While the present teachings are described in conjunction with various embodiments and examples, it is not intended that the present teachings be limited to such embodiments. On the contrary, the present teachings encompass various alternatives, modifications and equivalents, as will be appreciated by those of skill in the art, which may be made therein without departing from the spirit and scope of the invention.

1. A method of fabricating metal interconnects with reduced electromigration, the method comprising:
a. depositing metal interconnects on a substrate comprising electronic devices;
b. depositing a layer on the metal interconnects; and
c. doping the layer with at least one dopant having a dopant concentration that increases an electromigration resistance of the metal atoms.

2. The method of claim 1 wherein the layer comprise at least one of a dielectric material, a semiconductor material and a metal.

3. The method of claim 1 wherein the metal interconnects comprise of at least one of Cu, Al, Ag, Au, Ti, Ta, and W and alloys thereof.

4. The method of claim 1 wherein the doping the layer comprises ion implanting the layer with the at least one Group 5A and Group 6A periodic table element dopant.

5. The method of claim 1 wherein the doping the layer comprises exposing the metal interconnects to dopant atoms while depositing the layer.

6. The method of claim 1 wherein the doping the layer with at least one dopant comprises introducing dopant atoms in-situ during deposition.

7. The method of claim 1 wherein the doping the layer with at least one dopant comprises doping the layer with at least one Group 5A and Group 6A periodic table element dopant.

8. The method of claim 1 further comprising depositing dopant material on the metal interconnects prior to depositing the layer on the metal interconnects.

9. The method of claim 1 wherein the doping the layer with at least one dopant comprises depositing dopant containing material using at least one of chemical vapor deposition, physical vapor deposition, and atomic layer deposition.

10. The method of claim 1 wherein the doping the layer comprises varying process parameters during doping to achieve a predetermined dopant concentration gradient in the layer that improves the resistance to electromigration of metal atoms.

11. The method of claim 1 wherein the depositing the layer comprises depositing the layer by at least one of chemical vapor deposition, physical vapor deposition, and atomic layer deposition.

12. A method of fabricating metal interconnects with reduced electromigration, the method comprising:
a. depositing metal interconnects on a substrate comprising electronic devices; and
b. depositing a dopant containing layer on a surface of the metal interconnects, wherein a dopant concentration profile in the dopant containing layer is chosen to achieve a desired resistance to electromigration of metal atoms.

13. The method of claim 12 wherein the dopant containing layer comprises at least one element selected from Group 4A, 5A, and 6A periodic table elements.

14. The method of claim 12 wherein the metal interconnects are formed of at least one of Cu, Al, Ag, Au, Ti, Ta, and W and alloys thereof.

15. The method of claim 12 wherein the thickness of the dopant containing layer is in the range of 1-300 nm.

16. The method of claim 12 wherein the depositing the dopant containing layer comprises performing at least one of chemical vapor deposition, physical vapor deposition, atomic layer deposition, and electroless deposition.

17. The method of claim 12 wherein the dopant concentration in the dopant containing layer is uniform.

18. The method of claim 12 wherein the dopant concentration in the dopant containing layer is non-uniform in at least one direction.

19. The method of claim 12 wherein the dopant concentration in the dopant containing layer is varied during the deposition of the dopant containing layer.

20-25. (canceled)
